(19) United States
(12) Patent Application Publication
(10) Pub. No.: US 2017/0047513 A1
(43) Pub. Date: Feb. 16, 2017

(54) PROTON RESISTIVE MEMORY DEVICES AND METHODS

(71) Applicant: University of Washington, Seattle, WA (US)

(72) Inventors: Marco Rolandi, Seattle, WA (US); Erik Josberger, Seattle, WA (US); Yingxin Deng, Seattle, WA (US)

(73) Assignee: University of Washington, Seattle, WA (US)

(21) Appl. No.: 15/306,041

(22) PCT Filed: Apr. 21, 2015
(86) PCT No.: PCT/US2015/026942

§ 371 Date: Oct. 21, 2016

Related U.S. Application Data
(60) Provisional application No. 61/982,193, filed on Apr. 21, 2014.

(51) Int. Cl. H01L 45/00; H01L 23/522; G11C 13/00; H01L 23/528

(52) U.S. Cl. CPC H01L 45/1266; H01L 45/08; H01L 45/1233; H01L 45/1246; H01L 45/149; H01L 23/528; H01L 23/5226; G11C 13/0016; G11C 13/004; G11C 13/0069; H01L 45/1226; G11C 2213/12; G11C 2213/35; G11C 2213/52; G11C 2013/005; G11C 2013/009

(57) ABSTRACT

Disclosed herein is a memory device operating based on proton conduction between a source electrode and a drain electrode through a proton-conducting layer. As the memory device operates, protons from the source migrate through the proton-conducting layer and into the drain electrode. The memory device exhibits memory, in the form of changing net conductivity, based on the amount of protons conducted from source to drain. The memory device can be reset by regenerating the source electrode (e.g., through electrical or chemical action). The memory device can be incorporated into an integrated circuit as a memory element. Related methods of using the memory device are also disclosed.

### CROSS-REFERENCE TO RELATED APPLICATION

This application claims the benefit of U.S. Provisional Application No. 61/982193, filed Apr. 21, 2014, the disclosure of which is hereby incorporated by reference in its entirety.

### STATEMENT OF GOVERNMENT LICENSE RIGHTS

This invention was made with Government support under DE-SC0010441 awarded by the U.S. Department of Energy; and under DMR 1150630, awarded by the National Science Foundation. The Government has certain rights in the invention.

### BACKGROUND

In a chemical synaptic connection, neurotransmitters are released from the pre-synaptic neuron into the synaptic cleft upon arrival of an action potential. These neurotransmitters diffuse across the synaptic cleft, couple with the receptors in the post-synaptic neuron, and trigger a subsequent action potential in the post-synaptic neuron. After firing, the pre-synaptic neuron runs out of neurotransmitters for release into the synaptic cleft upon the arrival of a subsequent action potential. As a consequence, the action potential is not transmitted to the post-synaptic neuron. This temporary interruption of the synaptic connection is referred to as short-term depression (STD). STD is an important form of signal modulation in the brain.

With the recent physical demonstration of memristive-based devices, low-power two terminal devices with memory and learning functions have advanced electronics and neuromorphic computing. In neuromorphic computing, CMOS and transistor circuits are designed to mimic architectures in the brain and synaptic connections between neurons whose conductivity is influenced by prior events. In memristive devices, typically slow moving ions are coupled with fast moving electrons. Ionic motion affords memory, with electronic current as the output signal.

Despite recent development of certain resistive devices having memory, improved architectures that facilitate improved characteristics and simplified operation are desirable.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

In one aspect, a memory device is provided. In one embodiment, the memory device operates based on proton resistivity and is capable of switching a device state between a high conductivity state and a low conductivity state, the memory device comprising:

a source electrode comprising palladium, palladium hydride, or a combination thereof;

a drain electrode comprising palladium, palladium hydride, or a combination thereof; and

a proton-conducting layer separating the source electrode and the drain electrode, wherein the proton-conducting layer blocks electron transport;

wherein the memory device is configured to operate by applying a first voltage between the source electrode and the drain electrode, thereby causing hydrogen ion transport from the source electrode into the proton-conducting layer and from the proton-conducting layer into the drain electrode to provide a hydrogen-depleted source electrode and a hydrogen-rich drain electrode; and

wherein the device state has memory, based on conductivity of the source electrode and the drain electrode, that depends on the amount of charge as H+ ions that has been transferred through the proton-conducting layer.

In another aspect, a memory element is provided. In one embodiment, the memory element includes at least one memory device according to the disclosed embodiments incorporated into an integrated circuit.

In another aspect, a method of operating a memory device according to any of the disclosed embodiments is provided. In one embodiment, the method includes:

providing the memory device in a loaded state, wherein the source electrode comprises palladium hydride and wherein the source electrode and the drain electrode are in electrical communication with a voltage source; and

applying a first positive voltage from the voltage source between the source electrode and the drain electrode, thereby causing hydrogen ion transport from the source electrode into the proton-conducting layer and from the proton-conducting layer into the drain electrode to provide a discharged state that includes a hydrogen-depleted source electrode and a hydrogen-rich drain electrode, wherein applying the first voltage results in a discharge current due to hydrogen ion transport between the source electrode and the drain electrode.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1A schematically illustrates a proton resistive memory device in operation, in accordance with embodiments disclosed herein. A voltage (V_{SD}) is applied across two PdHₓ contacts separated by a proton-conducting layer. A H⁺ current (I_{SD}) flows from the source (left) to the drain (right). This H⁺ current depletes the PdHₓ source of hydrogen to form Pd (not proton conducting) and the protonic device is discharged.

FIG. 1B schematically illustrates a proton resistive memory device in a discharged state, in accordance with embodiments disclosed herein.

FIG. 1C schematically illustrates a proton resistive memory device in a “vertical stack” configuration, in accordance with embodiments disclosed herein.

FIG. 2A is a microscope image of a PdHₓ-Nafion proton resistive memory device, in accordance with embodiments disclosed herein. Lithographically patterned source and drain contacts 30 μm wide are separated by a 1 μm gap.

FIG. 2B graphically illustrates current (I_{SD}) as a function of time for an exemplary proton resistive memory device 30 μm wide by 500 μm long.

FIG. 2C graphically illustrates current spike behavior (V_{SD}=1 V) for exemplary proton resistive memory devices as a function of PdHₓ contact thickness.

FIG. 2D graphically illustrates I_{SD} dependence on V_{SD} and I_{SD} at t=0 s for an exemplary proton resistive memory device. The contacts are 10 nm thick PdHₓ and the Nafion deposition on the source contact is limited to an area 11 μm×30 μm with SU-8.

FIGS. 3A, 3B, 4A, 4B, 5A, and 5B combine to illustrate memory behavior of an exemplary proton resistive memory devices. FIG. 3A is a schematic side view of the device in an ON state. FIG. 3B shows micrographs of a vertical stack device in the ON state V_{SD}=0 V, where lighter areas are PdHₓ and darker areas are Pd. FIG. 4A is a schematic side view of the device in an OFF state after a V_{SD} pulse and resulting I_{SD} spike depletes the PdHx source of hydrogen to form Pd. FIG. 4B shows a micrograph of the device of FIG. 3B in the OFF state V_{SD}=1.25 V. FIG. 5A is a schematic side view of the device in a RESET state, wherein a negative V_{SD} injects H⁺ back into the source to form PdHₓ and restores the devices from depression. FIG. 5B shows a micrograph of the device of FIGS. 3B and 4B in the RESET state V_{SD}=−1.25 V.

FIG. 6 graphically illustrates ON and OFF switching in a representative device. Three positive SET pulses (V_{SD}=1.25 V, 0.25 s) and a negative RESET pulse (V_{SD}=1.25 V, 0.25 s) were applied.

FIG. 7 graphically illustrates an I-V curve for a representative device, showing the hysteresis in the PdHₓ-Nafion system.

FIG. 8 graphically illustrates simulated device current.

FIG. 9 graphically illustrates the time scale of representative device depletion dependence on atmospheric hydrogen concentration. This device has a 60 nm Pd layer and no limiting SU-8 layer and a corresponding long timescale for depletion. A 2.5% H₂ concentration in the atmosphere corresponds to a PdHₓ with smaller x than when a 5.0% concentration of H₂ in the atmosphere is used. As a result, tₛₚᵢₖₑ that corresponds to full depletion of H from PdHₓ is shorter.

FIG. 10 graphically illustrates total charge flux during an I_{SD} spike of representative device. Plot of total charge flux required for complete depletion of PdHₓ source contact as a function of V_{SD} and Pd thickness. Devices have no SU8 to limit contact area. Charge is calculated by

$$Q = {{\int }^{t = {t}_{spike}}}_{t = 0} {I}_{SD} d t .$$

The equilibrium current measured well after I_{SD} pulse is used as baseline to normalize the data. The total charge flux across the device for full depletion is proportional to the Pd thickness as thicker PdHₓ source contact contains more H to be depleted. V_{SD} has a minimal effect on the total charge, although lower voltages correspond to smaller I_{SD} and longer tₛₚᵢₖₑ.

FIG. 11 graphically illustrates measurement of ON and OFF current of representative device. When in the ON state, the device is read by a V_{SD} of 0.3V, which results in a current (I_{SD}) of 0.8 μA. A 1.25V pulse then depletes the device, putting it into the OFF state. While OFF, a voltage of 0.3V results in only 0.1 μA of current. The Pd contact is 60 nm thick.

### DETAILED DESCRIPTION

Disclosed herein is a memory device operating based on proton conduction between a source electrode and a drain electrode through a proton-conducting layer. As the memory device operates, protons from the source migrate through the proton-conducting layer and into the drain electrode. The memory device exhibits memory, in the form of changing net conductivity, based on the amount of protons conducted from source to drain. The memory device can be reset by regenerating the source electrode (e.g., through electrical or chemical action). The memory device can be incorporated into an integrated circuit as a memory element. Related methods of using the memory device are also disclosed.

In one aspect, a memory device is provided. In one embodiment, the memory device operates based on proton resistivity and is capable of switching a device state between a high conductivity state and a low conductivity state, the memory device comprising:

a source electrode comprising palladium, palladium hydride, or a combination thereof;

a drain electrode comprising palladium, palladium hydride, or a combination thereof; and

a proton-conducting layer separating the source electrode and the drain electrode, wherein the proton-conducting layer blocks electron transport;

wherein the memory device is configured to operate by applying a first voltage between the source electrode and the drain electrode, thereby causing hydrogen ion transport from the source electrode into the proton-conducting layer and from the proton-conducting layer into the drain electrode to provide a hydrogen-depleted source electrode and a hydrogen-rich drain electrode; and

wherein the device state has memory, based on conductivity of the source electrode and the drain electrode, that depends on the amount of charge as H+ ions that has been transferred through the proton-conducting layer.

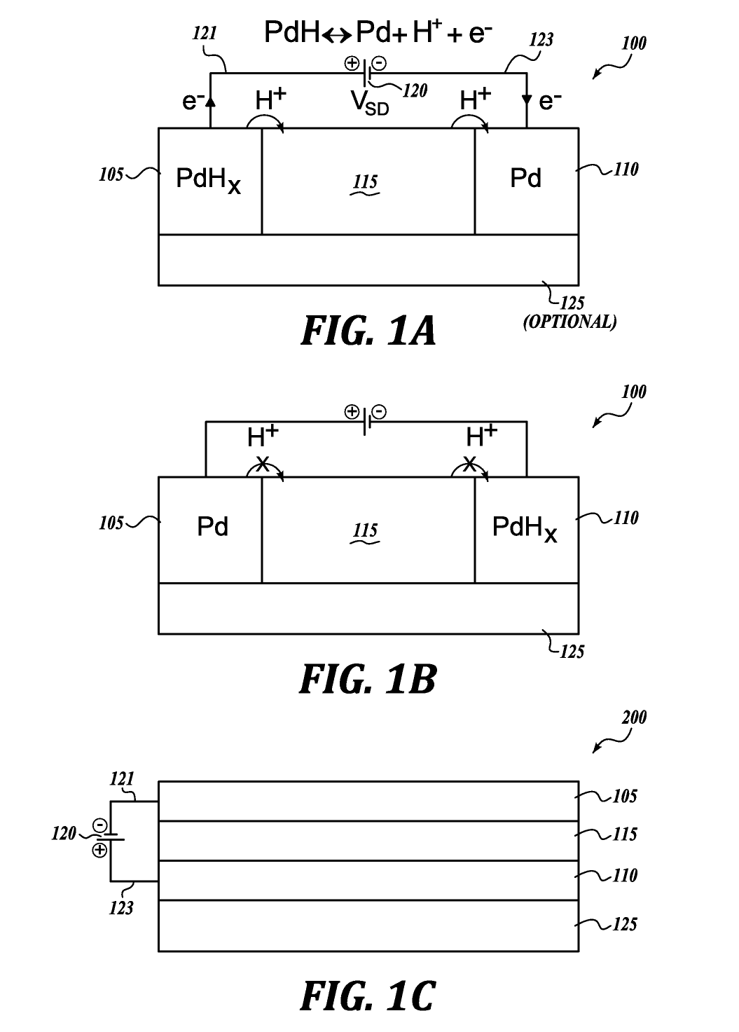

The memory device can be arranged in any configuration that disposes the proton-conducting layer between the source electrode and the drain electrode. Representative embodiments include horizontal devices (e.g., FIGS. 1A and 1B) and vertical stack devices (e.g., FIG. 1C).

The operation of the memory devices will now be described in relation to a horizontal configuration. However, the descriptions and operating principles of horizontal devices are also applicable to vertical devices, unless otherwise specified. As used herein, the term “about” indicates that the subject number can vary plus or minus 5% and remain within the described embodiment.

### Horizontal Device Configuration

In one embodiment, the memory device further comprises an insulating substrate upon which the source electrode, the drain electrode, and the proton-conducting layer are disposed. Referring now to FIG. 1A, a representative horizontally configured memory device 100 is illustrated schematically. The memory device 100 include a source electrode 105 that comprises palladium hydride (PdHₓ) and a drain electrode 110 that comprises palladium (Pd). In between the two electrodes 105 and 110 is a proton-conducting layer 115 that is configured to allow protonic transport but block electron transport. In the illustrated embodiment, an insulating substrate 125 (e.g., and insulating oxide layer), supports the source 105, drain 110, and a proton-conducting layer 115. The substrate 125 enables easy fabrication of horizontal devices, as it allows one or more of the supported features 105, 110, and 115 to be patterned using lithographic techniques, such as photolithography. Representative substrate materials include glass, semiconductors with an insulating layer (e.g., silicon/oxide) and polymers (e.g., polyolefins).

The memory device 100 operates (“ON”) by applying a voltage (V_{SD}) between the source electrode 105 and the drain electrode 110. The voltage is applied by a voltage source 120 through electrical connections 121 and 123 to the source electrode 105 and the drain electrode 110, respectively. A positive voltage applied to the source electrode 105 operates the memory device to “discharge” by driving protons from the source electrode 105 into the proton-conducting layer 115 and then from the proton-conducting layer 115 to the drain electrode 110. The movement of protons through the memory device 100 results in a “net conductivity” between the source electrode 105 and the drain electrode 110 through the proton-conducting layer. Net conductivity indicates that the device properties change, although the fundamental conductivities of the electrodes and proton-conducting layer do not change—only the relationship between them changes in a way that affects the total device conductivity. The net conductivity allows electrons to flow in the opposite direction within the circuit, thereby allowing the electronic/protonic characteristics to be measured.

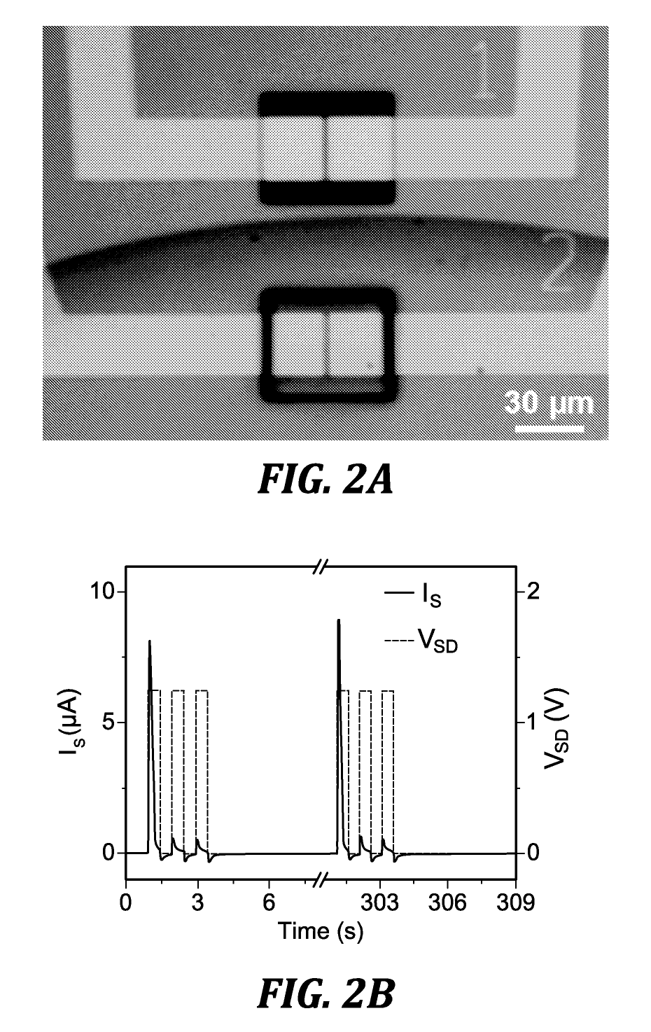

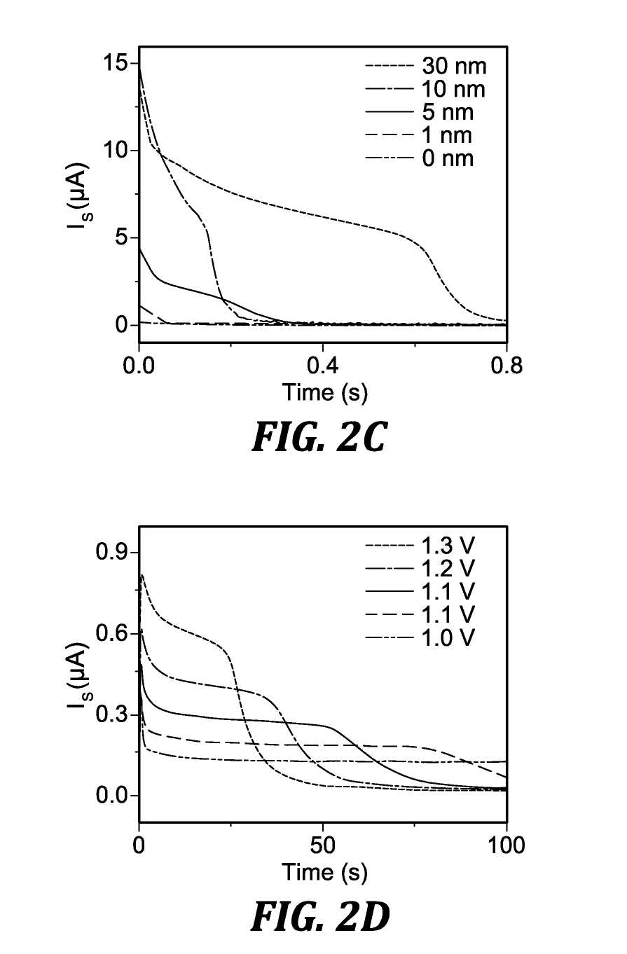

Referring now to FIG. 1B, the same basic memory device 100 as illustrated in FIG. 1A is now illustrated in an “OFF” state, wherein the source electrode 105 has been transformed into Pd through the loss of protons to the drain electrode 110, which become PdHₓ. The “X” arrows in FIG. 1B illustrate the condition wherein no protons can flow through the memory device 100 and therefore no net conductivity exists. The memory device 100 will not pass protons or electric current through the circuit even if a further voltage is applied. This state is illustrated in FIG. 2B, where current spikes during initial depletion of the memory device upon application of a voltage, but further voltage applications fail to generate current. This OFF state is analogous to the short-term depression (STD) demonstrated by synapses.

Therefore, the memory device 100 exhibits device memory by changing net conductivity as the device is operated. By interrogating the net conductivity of the memory device 100, its “state” can be determined. The memory device state can be ON, OFF, or any number of intermediate states, based on predetermined net conductivity characteristics.

In order to “reset” the memory device 100, the source electrode 105 is regenerated. This process can be accomplished by applying an opposite voltage than was used to discharge the device. Typically a positive voltage at the source electrode 105 drives the device 100 in the ON state and a negative voltage resets the device 100. Resetting the device 100 electrically provides the benefit of simply moving the protons back to the source electrode 105 from the drain electrode 110.

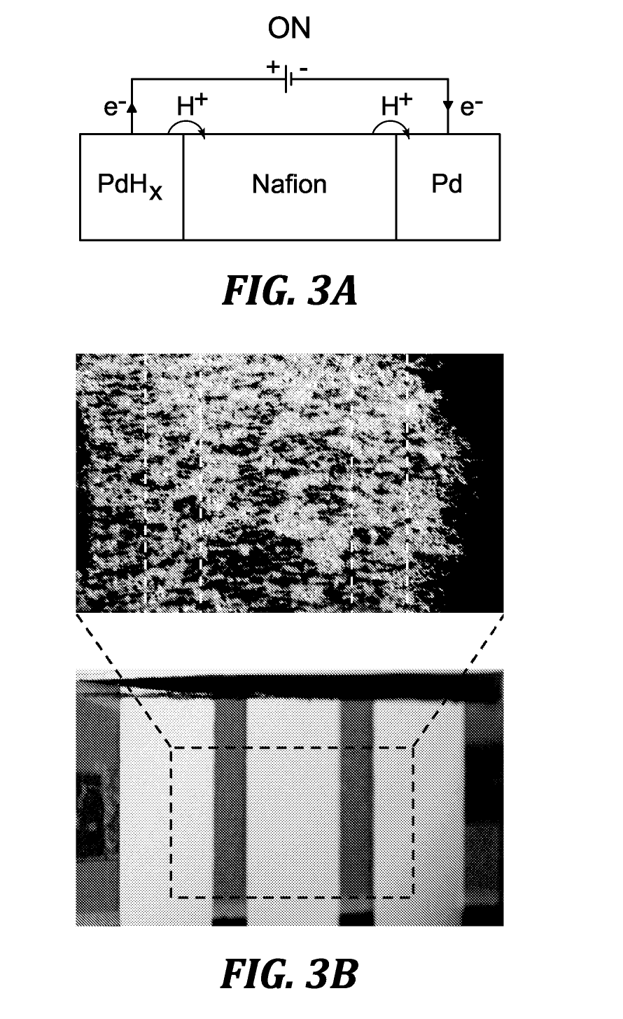

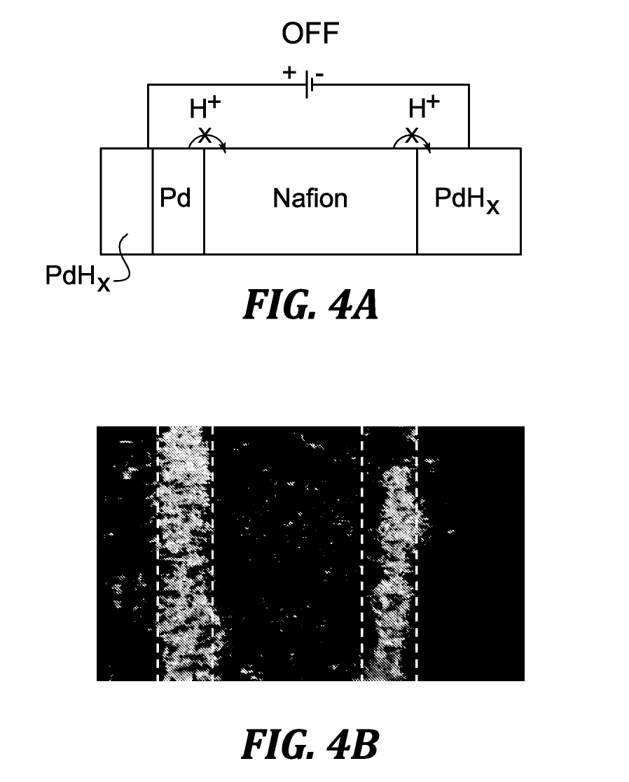

The ON, OFF, and RESET states are all illustrated schematically in FIGS. 3A, 4A, and 4B, respectively.

Furthermore, chemical regeneration can be used to reset the source electrode 105. Chemical regeneration includes exposing the source electrode 105 to hydrogen gas to form palladium hydride. The chemical reset does not transform the drain electrode 110 back to palladium, but it instead remains palladium hydride. Therefore, if the device 100 is run in a mode where both the source electrode 105 and drain electrode 110 are palladium hydride, hydrogen gas is generated at the drain electrode 110 to dispose of excess hydrogen in the system. Given the dangerous properties of hydrogen gas, the chemical recharging method may be disfavored in certain contexts.

In one embodiment, the memory device does not operate by an electrode other than the source electrode and the drain electrode. In such an embodiment, only the source electrode and drain electrode affect operation of the memory device. Certain prior art device architectures require a third (e.g., gate) electrode to operate a memory device. The present memory devices are superior by not requiring a third electrode to operate. Furthermore, it will be appreciated that vertical stack memory devices as disclosed herein have dimensions that would make a gate electrode impossible to integrate into the device, due to the thinness of the exposed edges of the proton-conducting layer within the stack. Accordingly, in one embodiment, the memory device does not include a gate electrode disposed on a side of the insulating substrate opposite from the proton-conducting layer.

In the horizontal configuration, a representative electrode thickness is about 10 nm to 100 nm thick and the proton-conducting layer is about 100 nm to 1 micron thick.

The geometry of the device can be tailored to the desired device characteristics. Because the device charge capacity is based on the amount of palladium hydride in the source electrode, the size of the source electrode is a primary defining device parameter. In one embodiment the source electrode has an area of 1 micron² to 10 mm². In one embodiment the source electrode has an area of 100 microns² to 1 mm². Exemplary electrode sizes include 30 microns×10 microns and 20 microns×500 microns (areas of 200 microns² and 1500 microns², respectively). The drain electrode can be sized similarly to the source electrode, although the dimensions of the two are not necessarily the same. Generally, the source electrode is the same volume or larger than the drain electrode, due the desire to maximize charge capacity of the device (in the form of palladium hydride).

The gap between the electrodes is filled with the proton-conducting layer. The size of the gap (linear distance from source to drain electrode) affects switching speed (the time required to turn the device OFF. Devices gain speed linearly with gap size and contact length (in the horizontal configuration).

An illustrative example is based on a device with electrodes of width 10 μm, length 10 μm, and thickness 10 nm, with a 1 μm gap between source and drain. Therefore, a 10 nm gap produces a 100× decrease in switching time, while an electrode that is 10 nm long gives a 1000× increase in speed. The width of the contacts affects only the current. Reducing the contact width to 10 nm reduces the current by 1000×. In total, reducing the contact volume by 10⁶ reduces the switching charge by 10⁶. Electrode width is measured in the direction parallel to the electrode gap in horizontal devices (see FIG. 2A for an illustrative example where the electrode width parallels the gap; the electrode length is perpendicular).

The size of the electrode gap is limited on the upper end by resistance in the proton-conducting layer, as a large gap size will not facility proton transfer. In one embodiment, the electrode gap is 1 nm to 100 microns. In one embodiment, the electrode gap is 10 nm to 10 microns. In one embodiment, the electrode gap is 500 nm to 5 microns.

The turn-on voltage required to operate the horizontal device varies based on device configuration and the composition of the proton-conducting layer. In one embodiment, the turn-on voltage is 0.5 V to 5 V. Voltages operated at greater than 1.5 V (“high voltage”) result in hydrolysis and device failure. Therefore, any high-voltage operation is performed in a water-free environment. Such a controlled environment can be achieved using known microelectronics packaging techniques. In one embodiment, the turn-on voltage is 0.5 V to 1.5 V. In one embodiment, the turn-on voltage is 0.75 V to 1.4 V.

Exemplary horizontal devices have source and drain contacts of size 10 μm×10 μm×10 m, and are separated by a 1 μm gap. Such devices, formed with Nafion as the proton-conducting layer, require 1.0-1.3 V to turn off within 25 ms, with a current of about 10 μA. Reading the device uses 0.5-0.8 V, drives 100 nA of current, and is limited in time only by external measurement equipment.

### Vertical Device Configuration

In one embodiment, the source electrode, the drain electrode, and the proton-conducting layer are arranged vertically in a stack. As mentioned above, the operation of a vertical memory device is similar to that of a horizontal memory device, such as that described above with reference to FIGS. 1A and 1B. FIG. 1C schematically illustrates a proton resistive memory device in a “vertical stack” configuration, in accordance with embodiments disclosed herein. In FIG. 1C, the vertical memory device 200 includes an analogous source electrode 105, drain electrode 110, and proton-conducting layer 115. Accordingly, in one embodiment, the proton-conducting layer is disposed on the drain electrode and the gate electrode is disposed on the proton-conducting layer.

An optional substrate 125 is a foundation for the device 200. A voltage source 120 is connected by leads 121 and 123 to the source electrode 105 and drain electrode 110 in order to drive the device 200. In one embodiment, the memory device further comprises electrical leads configured to connect the source electrode and the drain electrode to a voltage source.

In certain embodiments, the memory device 200 is integrated into an integrated circuit. In one embodiment, the electrical leads 121 and 123 are electrical vias. Accordingly, electrical connections are made to the electrodes 105 and 110 in the form of electrical vias of the types known in the microelectronics industry.

While the device 200 illustrated in FIG. 1C is in a configuration where the drain electrode 110 is disposed on the bottom of the “stack,” the reverse is also possible in a separate embodiment (not illustrated) where the stack is arranged from the bottom up: substrate, source electrode, proton-transport layer, and drain electrode. This configuration essentially switches the positions of the electrodes 105 and 110 as illustrated in FIG. 1C. Accordingly, in one embodiment, the proton-conducting layer is disposed on the source electrode and the drain electrode is disposed on the proton-conducting layer.

In the vertical configuration, a representative electrode thickness is about 10 nm to 100 nm thick and the proton-conducting layer is about 100 nm to 1 micron thick.

The geometry of the vertical device can be tailored to the desired device characteristics. Because the device charge capacity is based on the amount of palladium hydride in the source electrode, the size of the source electrode is a primary defining device parameter. In one embodiment the source electrode has an area of 1 micron² to 1 cm². In one embodiment the source electrode has an area of 100 micron² to 1 mm². The drain electrode can be sized similarly to the source electrode, although the dimensions of the two are not necessarily the same. Generally, the source electrode is the same volume or larger than the drain electrode, due the desire to maximize charge capacity of the device (in the form of palladium hydride).

The turn-on voltage required to operate the vertical device varies based on device configuration and the composition of the proton-conducting layer. In one embodiment, the turn-on voltage is 0.5 V to 5 V. In one embodiment, the turn-on voltage is 0.5 V to 1.5 V. In one embodiment, the turn-on voltage is 0.75 V to 1.4 V.

In one embodiment, the vertical electrode gap is 1 nm to 1 micron. In one embodiment, the electrode gap is 5 nm to 100 nm. In one embodiment, the electrode gap is 5 nm to 20 nm.

Exemplary vertical devices have source and drain contacts of size 1 mm×1 mm×50 nm, and are separated by a 5 μm gap. Such devices, formed with Nafion as the proton-conducting layer, require 1.0-1.3 V to turn off within 0.25 sec, with a current of about 100 μA. Reading the device uses 0.5-0.8 V, drives 100 nA of current, and is limited in time only by external measurement equipment.

If the device parameters are the same for vertical and horizontal devices, the performance will be similar.

### Electrodes

The memory device includes a source electrode and a drain electrode. Both electrodes are based on a palladium/palladium hydride system in which the source electrode comprises palladium hydride and transfers protons to the drain electrode during operation of the device. When the palladium hydride is exhausted, the device is in the OFF state until regenerated. In one embodiment, the source electrode and the drain electrode both comprise palladium. In one embodiment, the source electrode and the drain electrode both comprise palladium hydride. In one embodiment, the source electrode comprises at least 90% palladium hydride, by weight. In one embodiment, the source electrode comprises at least 99% palladium hydride, by weight.

In one embodiment, the drain electrode comprises a palladium mass that is greater than or equal to a palladium hydride mass in the source electrode, on a molar basis. Charge transfer in the device is limited by whichever contact is smaller: the source or drain. Given that the source and drain are based on the same material, the naming conventions are defined primarily based on how the device is wired and which electrode has the larger molar mass (capacity to contain the hydride form).

The electrodes are defined by any methods known to those of skill in the art, including lithographic methods.

### Proton-Conducting Layer

The proton-conducting layer provides a material that allows proton transport but blocks electron transport. This property enables the device to operate based solely on proton movement.

Any material capable of facilitating proton transport while blocking electron transport can be used in the memory devices. In one embodiment, the proton-conducting layer comprises a proton-conducting material selected from the group consisting of proton-conducting ionomers, electronic insulators functionalized with proton-conducting compounds, biopolymers, metal organic frameworks, molten salts, and solid state electrolytes. Generally, ionomers developed for fuel cell membranes can be used at the proton-conducting ionomer. In one embodiment, the proton-conducting ionomer is selected from the group consisting of Nafion Aciplex, and Flemion.

In one embodiment, the proton-conducting layer is an electronic insulator functionalized with a proton-conducting compound. In one embodiment, the electronic insulator is selected from the group consisting of a porous oxide, such as silicon oxide, a metal organic framework, yttria, and organic and inorganic porous materials. In one embodiment, the proton-conducting compounds comprise sulfonate moieties or other acid or base moieties coupled to the electronic insulator.

In one embodiment, the porous semiconductor is porous silicon comprising an oxide layer and wherein the proton-conducting compound is a sulfonate terminated silane coupled to the porous silicon oxide layer. Porous silicon is an insulating material that is well-established in the microelectronics industry and would be particularly compatible with vertical stack memory devices, due to the ease and cost of manufacturing a vertical stack of two electrodes having a porous silicon layer between them. Given the surface area of porous silicon, ample area exists for surface functionalization that would provide proton-conducting properties. For example, attaching a sulfonate moiety to the porous silicon (e.g., via an alkyl-silane coupling) would provide the necessary proton transport properties while blocking electron transport.

### Integrated Circuits

As noted above, the disclosed memory devices can be integrated into integrated circuits. Therefore, in another aspect, a memory element is provided. In one embodiment, the memory element includes at least one memory device according to the disclosed embodiments incorporated into an integrated circuit.

In one embodiment, the memory element is defined in a semiconductor package. As used herein, the term “semiconductor package” refers to an integrated circuit that can be formed using traditional semiconductor processing methods and materials.

In one embodiment, the memory element further comprises electrical vias providing electronic communication from the integrated circuit to the source electrode and the drain electrode of the memory device.

In one embodiment, the electrical vias connect a voltage source to the source electrode and the drain electrode.

### Method of Memory Device Operation

In another aspect, a method of operating a memory device according to any of the disclosed embodiments is provided. In one embodiment, the method includes:

providing the memory device in a loaded state, wherein the source electrode comprises palladium hydride and wherein the source electrode and the drain electrode are in electrical communication with a voltage source; and

applying a first positive voltage from the voltage source between the source electrode and the drain electrode, thereby causing hydrogen ion transport from the source electrode into the proton-conducting layer and from the proton-conducting layer into the drain electrode to provide a discharged state that includes a hydrogen-depleted source electrode and a hydrogen-rich drain electrode, wherein applying the first voltage results in a discharge current due to hydrogen ion transport between the source electrode and the drain electrode.

By applying a positive voltage, the device operates in the ON state until proton transfer stops and the OFF discharged state begins.

In one embodiment, the memory device in the discharged state has a lower net conductivity between the source electrode and the drain electrode than in the loaded state.

In one embodiment, the discharge current ceases after the hydrogen-depleted source electrode contain no palladium hydride.

In one embodiment, the method further comprises a step of reloading the memory device by forming palladium hydride on the source electrode.

In one embodiment, reloading comprises applying a second voltage from the voltage source, opposite in polarity from the first voltage, between the source electrode and the drain electrode.

In one embodiment, reloading comprises exposing the source electrode to hydrogen gas.

In one embodiment, the method further comprises a step of determining a state of the memory device by testing the net conductivity between the source electrode and the drain electrode, wherein the conductivity is indicative of the amount of palladium hydride in the source electrode. This step relates to “reading” the state of the device. The device cannot be “read”—have its state determined—without operating the device, at least to a small extent. This is because protons must flow in order to observe a net conductivity. However, in order to read the device state without substantively impacting the state of the device, the read voltage is much smaller than the drive voltage. This greatly reduces the charge transferred. The current transport reduces non-linearly with voltage, meaning that a very small voltage reduction dramatically reduces the current.

The “read” voltage is less than the “drive” or “ON” voltage (i.e., the first positive voltage). In one embodiment, the read voltage is about 0.1 V to about 1 V. In one embodiment, the read voltage is about 0.4 V to about 0.8 V.

In one embodiment, the state of the memory device is considered to be ON if the conductivity is in a first conductivity range. In one embodiment, the first conductivity range is from about 1.4 S/m to about 2.1 S/m. This range is for a device with electrode width 30 μm, thickness 10 nm, and gap 1 μm.

In one embodiment, the state of the memory device is considered to be OFF if the conductivity is in a second conductivity range that is distinct from the first conductivity range. In one embodiment, the second conductivity range is from about 0.05 S/m to about 0.12 S/m. This range is for a device with electrode width 30 μm, thickness 10 nm, and gap 1 μm.

In one embodiment, the memory device comprises at least one other state than ON and OFF, wherein the at least one other state is in a third conductivity range that is distinct from the first conductivity range and the second conductivity range. In one embodiment, the third conductivity range is from about 0.28 S/m to about 0.42 S/m. This range is for a device with electrode width 30 μm, thickness 10 nm, and gap 1 μm.

The following example is included for the purpose of illustrating, not limiting, the described embodiments.

### EXAMPLE

In this example, we disclose fully ionic two-terminal devices in which protons provide both memory and output signal. These devices exhibit synaptic-like reversible short-term depression, device memory, and, in certain embodiments, can be turned “ON” and “OFF” with as little as 30 nJ of energy per bit.

In the protonic two-terminal device (FIGS. 1A and 1B), palladium hydride (PdHₓ) source and drain contacts inject and drain protons (H⁺) into and from the Nafion. FIG. 2A is a microscope image of a PdHₓ-Nafion proton resistive memory device, in accordance with embodiments disclosed herein. Lithographically patterned source and drain contacts 30 μm wide are separated by a 1 μm gap.

For each H⁺ injected into the Nafion, an excess electron is collected by the leads, which complete the circuit. The source and drain contacts in the protonic two-terminal devices are analogous to the pre- and post-synaptic neurons in a chemical synapse. Nafion is a proton-conducting and electron insulating polymer widely used as proton exchange membrane in fuel cells, with a proton conductivity of 0.078 S cm⁻¹. An applied voltage (V_{SD}) causes an H⁺ current (I_{SD}) to flow between source and drain contacts in the protonic device (FIG. 2B). This current depletes hydrogen from the PdHₓ source where in direct contact with the Nafion. This depletion creates a hydrogen concentration gradient in the PdHₓ and a subsequent diffusion flux inside the contact. For low current densities, the diffusion flux in the PdHₓ, the absorption of hydrogen from the H₂ atmosphere, and I_{SD} balance out and the PdHₓ contacts effectively function as protodes, the protonic equivalent of electrodes. For higher current densities, as in the Nafion channel, a region of the source contact fully depletes of hydrogen to form Pd. Pd can no longer inject H⁺ in the Nafion and I_{SD} decays as a function of time. As a result, a V_{SD} pulse produces a spike in I_{SD} as the contact depletes (FIG. 2B). This type of transient behavior has previously been observed in PdHₓ reversible electrodes in contact with an acidic solution. The reduction in signal transmission strength after a pulse for the protonic device closely resembles the short-term depression (STD) plasticity of a chemical synapse. In a chemical synapse, depletion of neurotransmitters from the presynaptic neuron results in no signal transmission across the synaptic cleft. Here, in close analogy to the chemical synapse, depletion of hydrogen from the PdHₓ source results in no H⁺ current across the device upon arrival of a subsequent voltage pulse. Similarly to STD, waiting a determined period of time (300 s) restores the initial behavior as the source contact replenishes hydrogen from the atmosphere. To corroborate this picture, we fabricate protonic devices with PdHₓ contacts of varying thicknesses (FIG. 2C). Thinner contacts deplete faster than thicker ones due to an overall lower amount of hydrogen available in the PdHₓ to be injected in the Nafion as H⁺. A similar effect is also observed by loading contacts of same thickness with less hydrogen by exposing them to a lower hydrogen concentration in the atmosphere (FIG. 9). FIG. 9 graphically illustrates the time scale of representative device depletion dependence on atmospheric hydrogen concentration. This device has a 60 nm Pd layer and no limiting SU-8 layer and a corresponding long timescale for depletion. A 2.5% H₂ concentration in the atmosphere corresponds to a PdHₓ with smaller x than when a 5.0% concentration of H₂ in the atmosphere is used. As a result, tₛₚᵢₖₑ that corresponds to full depletion of H from PdHₓ is shorter. Thicker contacts (30 nm and 10 nm) result in comparable device I_{SD}, while 5 nm PdHₓ contacts show lower I_{SD} most likely due to reduced contact quality. Contacts with an equivalent thickness of Au, but no PdHₓ (0 nm), result in little or no current as expected. Au is an excellent electronic conductor for source and drain contacts, but cannot inject H⁺ into the Nafion. A protonic device with limited contact area between the PdHₓ and the Nafion (FIG. 2D) affords switching speeds of 25 ms with an on-off ratio of approximately 100. The switching speed of the protonic device is comparable to the switching speed of a biological synapse. The switching speed depends on V_{SD}. For a Nafion channel with fixed resistance, a larger V_{SD} results in higher I_{SD} and faster source contact depletion (tₛₚᵢₖₑ). In these devices, V_{SD} is limited to ≦1.3 V to avoid water electrolysis. For a given contact volume, we assume that the PdHₓ source contains a fixed amount of H and the contact is fully depleted when all of the H travels across the device channel as H⁺. To confirm this observation, the total amount of charge (Q) flowing across the Nafion channel during an I_{SD} spike is calculated as equation (1):

Q=∫ₜ₌₀^{t=t}ₛₚᵢₖₑI_{SD}dt (1)

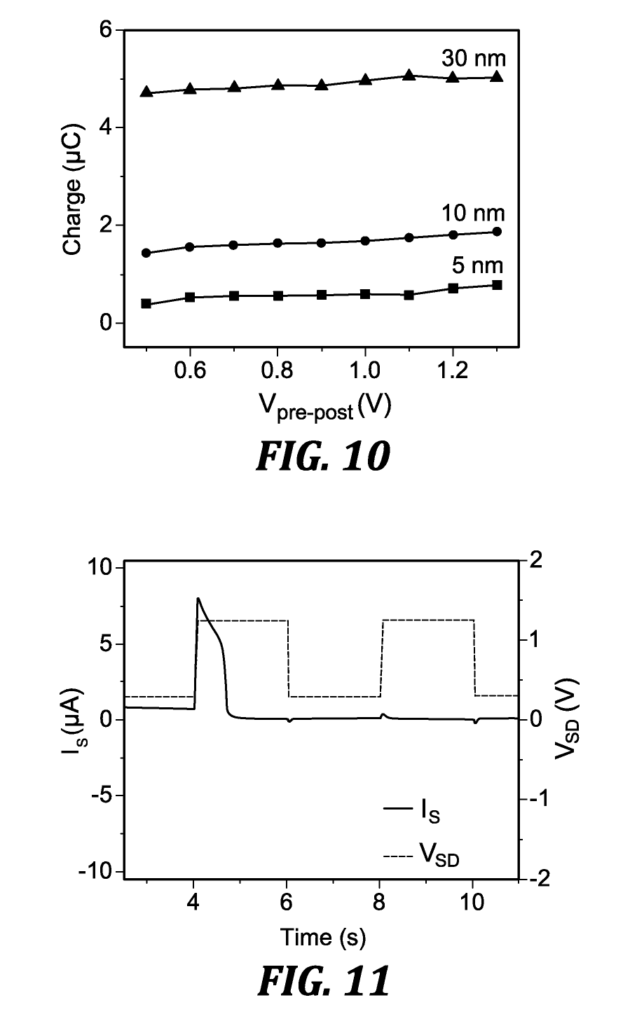

Integrating I_{SD} as a function of time gives the total number of H⁺ ions that flow across the channel, and therefore the total number of H atoms stored in the contact. The measured Q is constant as a function of V_{SD} and increases with PdHₓ thickness (FIG. 10). FIG. 10 graphically illustrates total charge flux during an I_{SD} spike. Plot of total charge flux required for complete depletion of PdHₓ source contact as a function of V_{SD} and Pd thickness. Devices have no SU8 to limit contact area. Charge is calculated by

$$Q = {{\int }^{t = {t}_{spike}}}_{t = 0} {I}_{SD} d t .$$

The equilibrium current measured well after I_{SD} pulse is used as baseline to normalize the data. The total charge flux across the device for full depletion is proportional to the Pd thickness as thicker PdHₓ source contact contains more H to be depleted. V_{SD} has a minimal effect on the total charge, although lower voltages correspond to smaller I_{SD} and longer tₛₚᵢₖₑ.

The conservation of charge as calculated in Equation 1 means that a larger I_{SD} results in a shorter tₛₚᵢₖₑ. For the same V_{SD}, I_{SD} depends on channel resistance, which is linearly depended on channel length. For a device with 3 μm channel length I_{SD}=4 μA and tₛₚᵢₖₑ=1.5 s, while an equivalent device with a 1 μm channel I_{SD}=15 μA and tₛₚᵢₖₑ=0.6 s. Devices with a shorter channel, and thus lower channel resistance, are expected to show a higher I_{SD} for the same V_{SD}, and a faster tₛₚᵢₖₑ. Overall, the STD behavior observed in the two-terminal protonic devices (FIG. 2B) is qualitatively similar to the STD behavior of a chemical synapse. Chemical synapses, however, also exhibit short-term potentiation and resulting spike timing dependence, which are both important for signal transmission in the brain.

In this work, we instead focus on the potential of creating a two-terminal device memory with reconfigurable “ON” and “OFF” states (e.g., as illustrated in FIGS. 3A-5B). A protonic memory in the ON state (FIG. 3A) conducts I_{SD} continuously with a small V_{SD} applied (as demonstrated in FIG. 11). FIG. 11 graphically illustrates measurement of ON and OFF current. When in the ON state, the device is read by a V_{SD} of 0.3V, which results in a current (I_{SD) of} 0.8 μA. A 1.25V pulse then depletes the device, putting it into the OFF state. While OFF, a voltage of 0.3V results in only 0.1 μA of current. The Pd contact is 60 nm thick, and has no SU-8 layer.

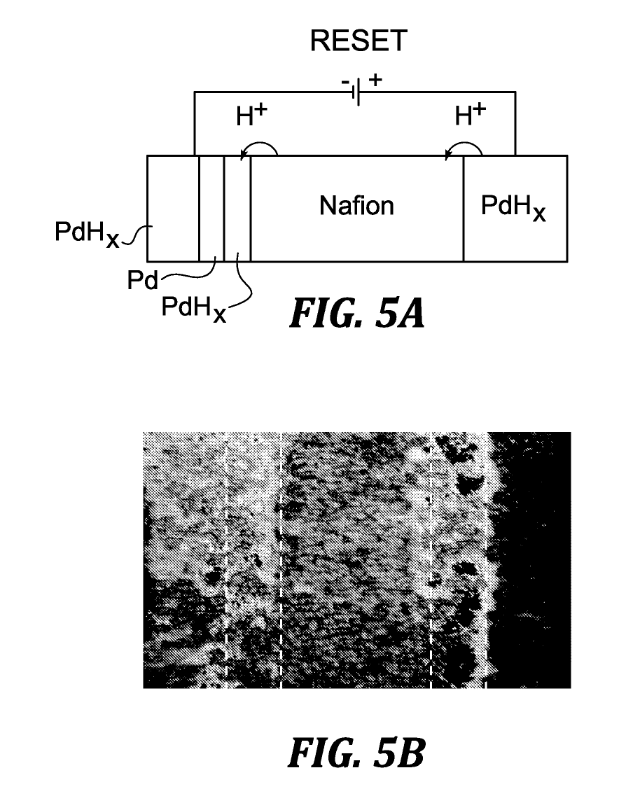

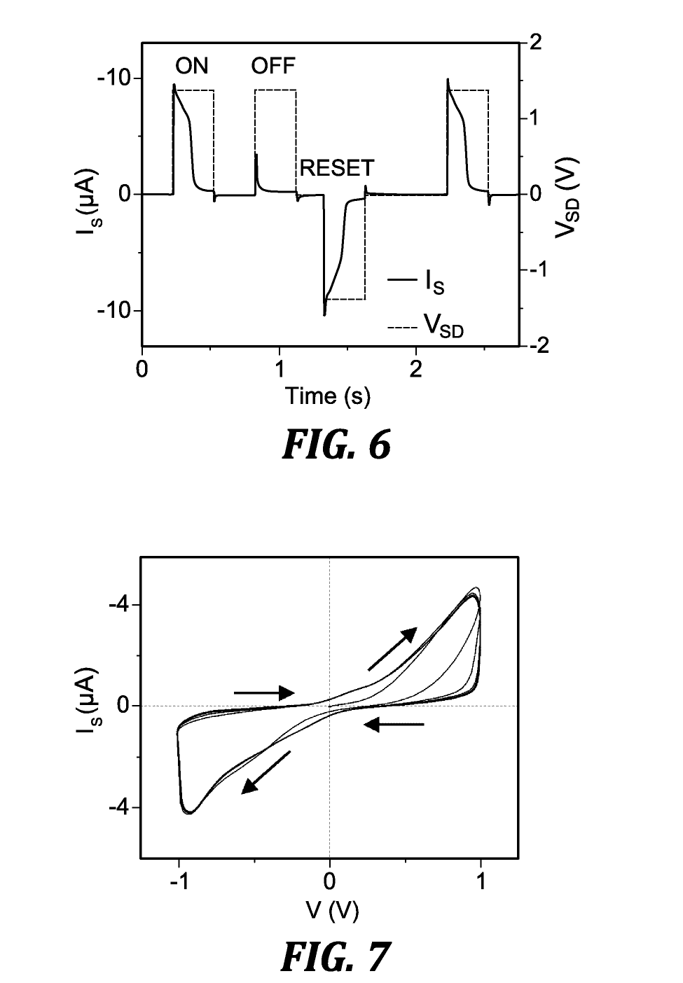

A positive V_{SD}=1.25 V turns the protonic memory OFF (FIG. 4A). A reverse V_{SD}=−1.25 V injects H⁺ back into the source contact to reform PdHₓ and RESETs the memory to the ON state (FIG. 5A). To observe this process, we fabricate sandwich (“vertical stack”) devices on transparent glass supports and image the source contact in the different memory states under an optical microscope (FIGS. 3B, 4B, and 5B, are the corresponding micrographs to FIGS. 3A, 4A, and 5A, respectively). Upon hydrogen absorption from the H₂ atmosphere, the source contact changes color from metallic Pd to white PdHₓ (FIG. 3B). A positive V_{SD} pulse depletes the PdHₓ of hydrogen, and the PdHₓ returns to metallic Pd as seen in the OFF state device (FIG. 4B). When the device is RESET, hydrogen is loaded as H⁺ from the Nafion channel back into the source contact to form white PdHₓ (FIG. 5B). This reloading is analogous to reuptake in neuronal synapses, which can actively pump the unused neurotransmitter back into the presynaptic neuron for reprocessing and re-release following a later action potential. Memory cycling is demonstrated from the I_{SD} output of a protonic device (FIG. 6) with the same structure as the one described in FIGS. 1A and 1B. FIG. 6 graphically illustrates ON and OFF switching. Three positive SET pulses (V_{SD}=1.25 V, 0.25 s) and a negative RESET pulse (V_{SD}=−1.25 V, 0.25 s) were applied. The magnitude and the time duration of the I_{SD} spike resulting from the RESET V_{SD} pulse are the same as the magnitude and the time duration of the I_{SD} spike for the ON-OFF V_{SD} pulse. This signifies that a fixed amount of hydrogen is shuttled between the source and drain contacts in the form of an H⁺ current in the Nafion (I_{SD}). It is conceivable that the ON-OFF cycle does not increase the concentration of H in the drain contact to x>0.6. The equilibrium pressure of H₂ increases exponentially when x is above 0.6. It is likely that additional hydrogen added to a contact that already has x=0.6 diffuses into the atmosphere instead of increasing the hydrogen loading of the PdHₓ. Cycling the protonic device by applying a 2 Hz, 1 V sine wave to V_{SD} confirms the device characteristics with a clear hysteresis between the ON and OFF states (FIG. 7). FIG. 7 graphically illustrates an I-V curve showing the hysteresis in the PdHₓ-Nafion system.

I_{SD} is the same in either direction, which is similar to unipolar resistive switching. Cycling is performed 22 times indicating reasonable reproducibility. Starting at V_{SD}=0 V and increasing V_{SD}, the device is in the ON state and turns OFF at up to V_{SD}=1V, at which point the source contact is fully depleted of H and is no longer capable of injecting H⁺ into the Nafion channel. The device stays OFF for V_{SD}>0 until the polarity of V_{SD} is reversed. A device in the OFF state for V_{SD}>0 V is in the ON state for V_{SD}<0 V because the PdHₓ drain contact is not depleted of H and is capable of injecting H⁺ into the Nafion channel. A V_{SD}<0 V depletes the drain contact of H and the device eventually turns OFF for V_{SD}=−1 V. At the same time, V_{SD}<0 V moves H⁺ back into the source contact. This replenishes the H in the PdHₓ source and puts the device is in the ON state for V_{SD}>0 V. The state of these devices is governed by the amount of charge flux that has gone through the device, specifically the amount of H³⁰ that is shuttled back and forth in the Nafion channel. As such, these protonic devices may have similar characteristics to memristors with the charge flux being the state variable. In these devices the protons that regulate the state of the device also provide the output signal, unlike in most memristors where ions control the state of the device and electrons are the output signal. However, in these protonic devices the hysteresis loop is not pinched with zero crossing, which is characteristic of memristors. The behavior of the protonic devices can be qualitatively described as two memristive diodes (the source and drain contacts) arranged back to back.

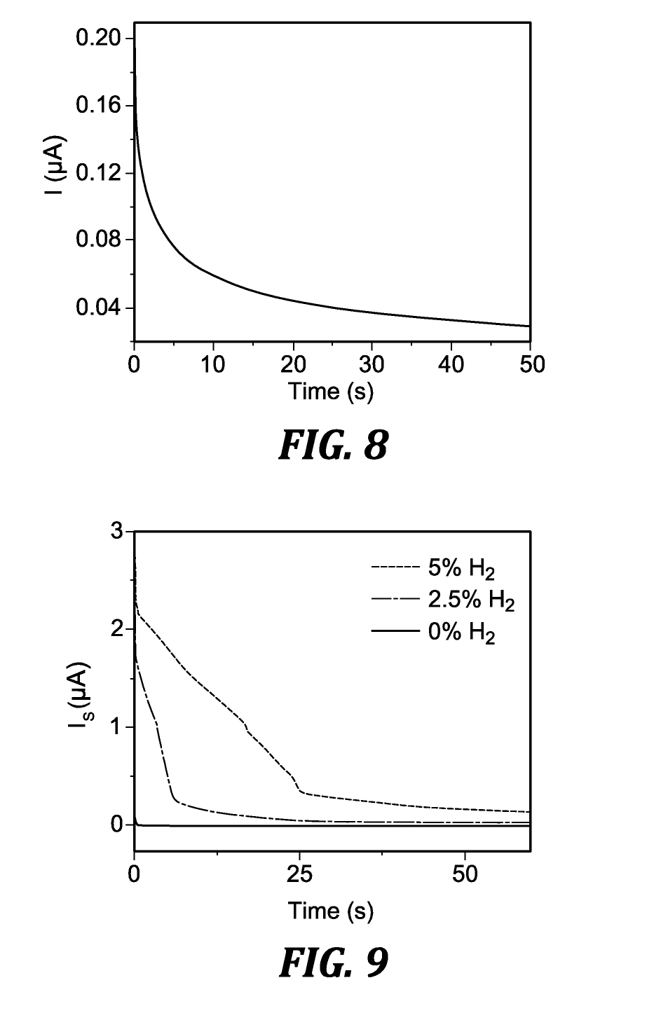

To better illustrate the workings of protonic devices, we developed a simple one-dimensional physical model using equations (2) and (3) to predict the current behavior of the devices, as illustrated in FIG. 8.

$$\begin{matrix}{J}_{H} = {D}_{H} \frac{d {n}_{H}}{d x} & ( 2 ) \\ {I}_{{H}^{+}} = A e {J}_{H} & ( 3 )\end{matrix}$$

wherein:

D_{H}=4×10¹¹ m²s⁻¹ and is the diffusion coefficient for H in palladium hydride;

n_{H}=4×10²² cm⁻³ and is the density of H in palladium hydride; and

x=from 0 to 10 μm and is the distance from the surface of the contact.

In this model the diffusion flux (J_{H}) of hydrogen inside the PdHₓ contact follows Fick's first law of diffusion and conservation of mass. For this simple model, we neglect any exchange of hydrogen between the PdHₓ and the surrounding H₂ atmosphere. Assuming continuity across the PdHₓ Nafion boundary, we postulate that the current of H⁺ in the Nafion channel (I_{H+} or I_{SD}) is equal to J_{H} in the last PdHₓ cell in contact with the Nafion times the charge of a proton (e) and the contact area of the device (A). Therefore, the hydrogen diffusion in the PdHₓ is driven by the induced electric drift of H⁺ from the contact-Nafion interface and along the Nafion channel, in a fashion similar to the transfer of H⁺ to an acidic water solution in the palladium hydrogen reversible electrode. This model does not include any trap states, or the accurate 2D device geometry, which likely affects the I_{SD} characteristics in the experimental protonic devices. Nonetheless, by setting I_{SD}=0.2 μA for t=0 we reproduce an I_{SD} time dependence that is consistent with the experimental results of our faster protonic devices (FIG. 2D). This model provides insights in the spatial dependence of the hydrogen concentration (x) in the PdHₓ source contact at different time points. As expected, a hydrogen-depleted region of Pd grows with time in the source contact and results in a smaller I_{SD} when the device is eventually turned from the ON to the OFF state. A consequence of the simple diffusion based characteristics of the protonic devices is the potential for ultra-low power computing.

Current devices (FIG. 2D) with micron size contacts are limited to about 30 nJ of energy per switching event. We estimate that a protonic memory device with 20 nm wide contacts may use as little as 30 fJ per operation, which is two orders of magnitude smaller than the energy used by a natural synapse (1 pJ).

### Experimental Section

Protonic micro devices are fabricated on p-type Si (Addison Engineering, B-doped, ρ=0.001 ohm cm⁻¹) with thermally grown silicon oxide (100 nm). Standard photolithography is used to define the metal contacts. Pd (thickness from 1 mm to 30 nm) with a 15 nm Cr adhesion layer is deposited via e-beam evaporation (Balzers PLS 500). To ensure consistency, contacts are kept at a 100 nm total thickness by adding Au between the Cr and Pd layers as needed. SU-8 is used to confine the Nafion covered area. 2 μL Nafion 117 solution (5% concentration) from Sigma Aldrich is drop-cast on top of the patterned silicon wafer and the solution is dried in a fume hood. For protonic sandwich devices, Pd (50 nm) is evaporated on glass slides with 5 mm contacts defined by shadow masking with tape. A porous cellulose membrane (VWR Tissue Wipe) immersed in the Nafion solution is sandwiched between the two Pd contacts. The cellulose membrane prevents short circuit and improves the connection. Measurements are performed with a semiconductor parameter analyzer (Agilent 4155C). A Rigol DG4062 function generator is used to create a pulse sequence and sinusoidal inputs. Device testing is performed on a Signatone H-100 probe station in a controlled atmosphere of 5% H₂, 95% N₂, at 75% relative humidity (RH). In 5% H₂ atmosphere, Pd absorbs H₂ to form PdHₓ (x=0.6). A finite difference model implemented in Matlab is used to calculate the diffusive flow of H within the contact. The simulated contacts are 30 μm wide by 10 nm thick, and are partitioned in 10 nm segments along a total contact length of 60 μm. D_{H}=4×10⁻¹¹ m² s⁻¹. Simulations are performed by repeating a two-step algorithm. First, the momentary inter-cell fluxes are computed based on the existing concentration in each cell. Second, the time is incremented by 1 μs, and new cell concentrations are computed from the given fluxes and conservation of mass.

### Switching Energy Estimate

The total energy required for a switching operation (E) is proportional the amount of charge (Q) displaced across the device according to equation (4):

E=QV_{SD} (4)

We calculate Q as equation (5):

Q=∫ₜ₌₀^{t=t}ₛₚᵢₖₑI_{SD}dt (5)

where tₛₚᵢₖₑ is the duration of a “OFF” or “RESET” pulse. OFF or RESET pulses are equal in magnitude and length.

For the device in FIG. 2D, according to equation 5 22 nC of charge are displaced by an “OFF” pulse across V_{SD}=1.3 V. According to equation 4 E=29 nJ. Following the trend in FIG. 2C, Q can be minimized by reducing the volume of the source contact. Here we assume that an “OFF” pulse fully depletes the PdHₓ source contact of H from x=0.6 to x=0. For a contact similar in size to current semiconductor devices (10 nm thick 20 nm wide and 20 nm long) this full depletion corresponds to 2.1×10⁵ hydrogen atoms or 26 fC of charge as H⁺ flowing from the source contact to the drain contact across V_{SD}=1.3 V. According to (1) E=34 fJ per operation.

While illustrative embodiments have been illustrated and described, it will be appreciated that various changes can be made therein without departing from the spirit and scope of the invention.

1. A memory device operating based on proton resistivity and capable of switching a device state between a high conductivity state and a low conductivity state, the memory device comprising:
a source electrode comprising palladium, palladium hydride, or a combination thereof;
a drain electrode comprising palladium, palladium hydride, or a combination thereof; and
a proton-conducting layer separating the source electrode and the drain electrode, wherein the proton-conducting layer blocks electron transport;
wherein the memory device is configured to operate by applying a first voltage between the source electrode and the drain electrode, thereby causing hydrogen ion transport from the source electrode into the proton-conducting layer and from the proton-conducting layer into the drain electrode to provide a hydrogen-depleted source electrode and a hydrogen-rich drain electrode; and
wherein the device state has memory, based on conductivity of the source electrode and the drain electrode, that depends on the amount of charge as H+ ions that has been transferred through the proton-conducting layer.

2. The memory device of claim 1, further comprising an insulating substrate upon which the source electrode, the drain electrode, and the proton-conducting layer are disposed.

3. The memory device of claim 2, wherein the memory device does not operate by an electrode other than the source electrode and the drain electrode.

4. The memory device of claim 2, wherein the memory device does not include a gate electrode disposed on a side of the insulating substrate opposite from the proton-conducting layer.

5. The memory device of claim 1, wherein the source electrode, the drain electrode, and the proton-conducting layer are arranged vertically in a stack.

6. The memory device of claim 5, wherein the proton-conducting layer is disposed on the source electrode and wherein the drain electrode is disposed on the proton-conducting layer.

7. The memory device of claim 5, wherein the proton-conducting layer is disposed on the drain electrode and wherein the source electrode is disposed on the proton-conducting layer.

8. The memory device of claim 5, further comprising electrical leads configured to connect the source electrode and the drain electrode to a voltage source.

9. The memory device of claim 8, wherein the electrical leads are electrical vias.

10. The memory device of claim 5, wherein the proton-conducting layer comprises a porous semiconductor covered in an insulating oxide layer.

11. The memory device of claim 1, wherein the source electrode and the drain electrode both comprise palladium.

12. The memory device of claim 1, wherein the source electrode and the drain electrode both comprise palladium hydride.

13. The memory device of claim 1, wherein the source electrode comprises at least 90% palladium hydride, by weight.

14. The memory device of claim 1, wherein the drain electrode comprises a palladium mass that is greater than or equal to a palladium hydride mass in the source electrode, on a molar basis.

15. The memory device of claim 1, wherein the proton-conducting layer comprises a proton-conducting material selected from the group consisting of proton-conducting ionomers, electronic insulators functionalized with proton-conducting compounds, biopolymers, metal organic frameworks, molten salts, and solid state electrolytes.

16. The memory device of claim 15, wherein the proton-conducting ionomer is selected from the group consisting of Nafion, Aciplex, and Flemion.

17. The memory device of claim 15, wherein the proton-conducting compounds comprise sulfonate moieties or other acid or base moieties coupled to the electronic insulator.

18. The memory device of claim 15, wherein the porous semiconductor covered in an insulating oxide layer is porous silicon comprising an oxide layer and wherein the proton-conducting compound is a sulfonate terminated silane coupled to the porous silicon oxide layer.

19. A memory element comprising at least one memory device according to claim 1 incorporated into an integrated circuit.

20. The memory element of claim 19, wherein the memory element is defined in a semiconductor package.

21. The memory element of claim 19, wherein the memory element further comprises electrical vias providing electronic communication from the integrated circuit to the source electrode and the drain electrode of the memory device.

22. The memory element of claim 21, wherein the electrical vias connect a voltage source to the source electrode and the drain electrode.

23. A method of operating a memory device according to claim 1, comprising:
providing the memory device in a loaded state, wherein the source electrode comprises palladium hydride and wherein the source electrode and the drain electrode are in electrical communication with a voltage source; and
applying a first positive voltage from the voltage source between the source electrode and the drain electrode, thereby causing hydrogen ion transport from the source electrode into the proton-conducting layer and from the proton-conducting layer into the drain electrode to provide a discharged state that includes a hydrogen-depleted source electrode and a hydrogen-rich drain electrode, wherein applying the first voltage results in a discharge current due to hydrogen ion transport between the source electrode and the drain electrode.

24. The method of claim 23, wherein the memory device in the discharged state has a lower net conductivity between the source electrode and the drain electrode than in the loaded state.

25. The method of claim 23, wherein the discharge current ceases after the hydrogen-depleted source electrode contain no palladium hydride.

26. The method of claim 23, further comprising a step of reloading the memory device by forming palladium hydride on the source electrode.

27. The method of claim 26, wherein reloading comprises applying a second voltage from the voltage source, opposite in polarity from the first voltage, between the source electrode and the drain electrode.

28. The method of claim 26, wherein reloading comprises exposing the source electrode to hydrogen gas.

29. The method of claim 23, further comprising a step of determining a state of the memory device by testing the net conductivity between the source electrode and the drain electrode, wherein the net conductivity is indicative of the amount of palladium hydride in the source electrode.

30. The method of claim 29, wherein the state of the memory device is considered to be ON if the conductivity is in a first conductivity range.

31. The method of claim 30, wherein the state of the memory device is considered to be OFF if the conductivity is in a second conductivity range that is distinct from the first conductivity range.

32. The method of claim 31, wherein the memory device comprises at least one other state than ON and OFF, wherein the at least one other state is in a third conductivity range that is distinct from the first conductivity range and the second conductivity range.
